(19) United States
(12) Patent Application Publication
(10) Pub. No.: US 2025/0218839 A1
(43) Pub. Date: Jul. 3, 2025

(54) STOCKER DEVICE AND SUBSTRATE PROCESSING APPARATUS

(71) Applicant: SEMES CO., LTD., Cheonan-si (KR)

(72) Inventors: Chang Suk OH, Cheonan-si (KR); Seung Hwan LEE, Cheonan-si (KR)

(73) Assignee: SEMES CO., LTD., Cheonan-si (KR)

(21) Appl. No.: 19/001,878

(22) Filed: Dec. 26, 2024

(30) Foreign Application Priority Data
Dec. 29, 2023 (KR) 10-2023-0196060

(51) Int. Cl. H01L 21/677; B25J 11/00; B65G 1/04

(52) U.S. Cl. CPC H01L 21/67769; B25J 11/0095; B65G 1/0464; H01L 21/6773; H01L 21/67733; B65G 2201/0297

(57) ABSTRACT

Disclosed is a stocker device provided on a front face of a substrate processing apparatus in which load ports are placed horizontally, the stocker device including: a loading unit located in front of the load ports and including shelves configured to store substrate accommodation containers; and a main frame including a container transfer device configured to transfer the substrate accommodation container between the shelves and the load port, in which the container transfer device is located above the load ports.

### CROSS-REFERENCE TO RELATED APPLICATIONS

This application claims priority to and the benefit of Korean Patent Application No. 10-2023-0196060 filed in the Korean Intellectual Property Office on Dec. 29, 2023, the entire contents of which are incorporated herein by reference.

### TECHNICAL FIELD

The present invention relates to a stocker device, and a substrate processing apparatus including the same.

### BACKGROUND ART

In general, in order to manufacture a semiconductor device, various types of processes, such as deposition, photography, and etching, are performed, and devices performing each of these processes are arranged in a semiconductor manufacturing line. In semiconductor manufacturing lines, various logistics and transfer are performed by using Overhead Hoist Transport (OHT).

The OHTs (transfer trolleys) operate in large quantities on tracks (rails), and there is an OHT control system that controls and manages all OHTs to control and manage the large quantity of OHTs.

However, additional operations of transfer trolleys are necessary in accordance with the increasing logistics movement in places with a large volume of goods, such as semiconductor production lines, but due to limited space and high cost of additional operation of transfer trolleys, the capacity increase due to logistics movement is insufficient. Therefore, if the quantity of goods transferred of transfer trolleys per unit time is large, there is a problem that the substrate processing operation in a semiconductor processing apparatus is not smooth due to the low processing speed per vehicle and the stagnation of the transfer trolley.

### SUMMARY OF THE INVENTION

The present invention has been made in an effort to provide a stocker device including a plurality of container loading units having a small share for improving throughput, and a substrate processing apparatus including the same.

The present invention has also been made in an effort to provide a stocker device that is easy to maintain, and a substrate processing apparatus including the same.

The present invention has also been made in an effort to provide a stocker device capable of optimizing a container transfer operation between a container loading unit and a load port, and a substrate processing apparatus including the same.

The problem to be solved by the present invention is not limited to the above-mentioned problems, and the problems not mentioned will be clearly understood by those skilled in the art from the descriptions below.

An exemplary embodiment of the present invention provides, a stocker device provided on a front face of a substrate processing apparatus in which load ports are placed horizontally, the stocker device comprising: a loading unit located in front of the load ports and including shelves configured to store substrate accommodation containers; and a main frame including a container transfer device configured to transfer the substrate accommodation container between the shelves and the load port, wherein the container transfer device may be located above the load ports.

According to the exemplary embodiment of the present invention, the loading unit may include: a carrying-in/out loading unit including a carrying-in/out shelf where the substrate accommodation container is loaded and unloaded bya ceiling transfer trolley; and a main loading unit including storage shelves configured to store the substrate accommodation containers transferred between the carrying-in/out loading unit and the load port.

According to the exemplary embodiment of the present invention, the loading unit may be configured to slide or open/close and move to the front of the main frame to secure a space for maintenance.

According to the exemplary embodiment of the present invention, the carrying-in/out loading unit may be located over the main loading unit.

According to the exemplary embodiment of the present invention, the carrying-in/out loading unit is fixedly installed on the main frame, and the main loading unit may be configured to slide or open/close and move to the front of the main frame to secure a space for maintenance.

According to the exemplary embodiment of the present invention, the main loading unit is configured such that the shelves are arranged in multiple stages in a vertical direction, and a first-stage shelf located at the lowermost stage among the shelves and a second-stage shelf located directly over the first-stage shelf may have a greater floor height than other shelves.

According to the exemplary embodiment of the present invention, a shelf located at the topmost portion of the loading unit may be configured to allow the substrate accommodation container to be transferred between the shelf and a ceiling traveling trolley.

According to the exemplary embodiment of the present invention, the container transfer device may include: a transfer robot including an arm configured to grip the substrate accommodation container; a horizontal driving unit configured to move the transfer robot in a horizontal direction; and a vertical driving unit configured to move the transfer robot in a vertical direction.

According to the exemplary embodiment of the present invention, the horizontal driving unit may be located above the load ports.

According to the exemplary embodiment of the present invention, the transfer robot may be configured to perform loading and unloading of the substrate transfer container on the carrying-in/out shelf or the storage shelf with the arm in an extended state, and performs loading and unloading of the substrate transfer container on the load port with the arm in a folded state.

An exemplary embodiment of the present invention provides, a substrate processing apparatus comprising: a main body including an index unit in which load ports on which substrate accommodation containers are placed are horizontally arranged on a front face; and a stocker device located in front of the index unit and configured to load and unload the substrate accommodation container, wherein the stocker device may include: a loading unit located in front of the load ports and configured to store the substrate accommodation container; and a main frame including a container transfer device configured to transfer the substrate accommodation container between the loading unit and the load port in a space above the load ports.

According to the exemplary embodiment of the present invention, the loading unit may be configured to slide to the front of the main frame to secure a space for maintenance.

According to the exemplary embodiment of the present invention, the loading unit may include: a carrying-in/out loading unit including a carrying-in/out shelf where the substrate accommodation container is loaded and unloaded by a ceiling transfer trolley; and a main loading unit including storage shelves storing the substrate accommodation container transferred between the carrying-in/out loading unit and the load port.

According to the exemplary embodiment of the present invention, the carrying-in/out loading unit may be located over the main loading unit, the index unit further includes an additional loading unit accessible by the container transfer device and configured to store the substrate accommodation container, and the additional loading unit is located above an index robot of the index unit.

According to the exemplary embodiment of the present invention, the carrying-in/out loading unit is fixedly installed on the main frame, and the main loading unit configured to slide to the front of the main frame to secure a space for maintenance.

According to the exemplary embodiment of the present invention, the main loading unit may be configured such that the shelves are arranged in multiple stages in a vertical direction, and a first-stage shelf located at the lowermost stage among the shelves and a second-stage shelf may located directly over the first-stage shelf have a greater floor height than other shelves.

According to the exemplary embodiment of the present invention, the container transfer device includes: a transfer robot including an arm configured to grip the substrate accommodation container; a horizontal driving unit configured to move the transfer robot in a horizontal direction; and a vertical driving unit configured to move the transfer robot in a vertical direction, and the horizontal driving unit may be located above the load ports, and the transfer robot configured to perform loading and unloading of the substrate transfer container on the load port with the arm in a folded state.

An exemplary embodiment of the present invention provides, a substrate processing apparatus comprising: a main body including a processing unit equipped with processing apparatuses that perform predetermined processing on a substrate, and an index unit which is located in front of the processing unit and in which load ports on which substrate accommodation containers are placed are horizontally arranged on a front face; and a stocker device located in front of the index unit and configured to load and unload the substrate accommodation container, wherein the stocker device includes: a loading unit including carrying-in/out shelves that are located in front of the load ports and where the substrate accommodation container is loaded and unloaded by a ceiling transfer trolley, and storage shelves located under the carrying-in/out shelves and configured to store the substrate accommodation container transferred between the carrying-in/out shelf and the load port; and a main frame including a container transfer device configured to transfer the substrate accommodation container between the loading unit and the load port in a space above the load ports, and the loading unit futher includes a moving frame slidably configured to move to the front of the main frame, and the storage shelves may be arranged in multiple stages in a vertical direction on the moving frame.

According to the exemplary embodiment of the present invention, the carrying-in/out shelves are fixedly installed on the main frame, and a storage shelf in a first stage located at the lowermost stage among the storage shelves and a storage shelf located in a storage shelf directly over the storage shelf in the first stage may have a greater floor height than other storage shelves, and the index unit further includes an additional loading unit accessible by the container transfer device and configured to store the substrate accommodation container, and the additional loading unit is located above an index robot of the index unit.

According to the exemplary embodiment of the present invention, the container transfer device includes: a transfer robot including an arm configured to grip the substrate accommodation container; a horizontal driving unit located above the load ports and configured to move the transfer robot in a horizontal direction; and a vertical driving unit configured to move the transfer robot in a vertical direction, and the transfer robot configured to perform loading and unloading of the substrate transfer container on the carrying-in/out shelf or the storage shelf with the arm in an extended state, and to perform loading and unloading of the substrate transfer container on the load port with the arm in a folded state.

According to the exemplary embodiment of the present invention, a small occupancy rate may be provided by disposing the container transfer device above the load port.

According to the exemplary embodiment of the present invention, maintenance is easy by moving the loading unit from the main frame.

According to the exemplary embodiment of the present invention, it is possible to optimize the container transfer operation between the loading unit and the load port.

The effect of the present invention is not limited to the foregoing effects, and those skilled in the art may clearly understand non-mentioned effects from the present specification and the accompanying drawings.

### BRIEF DESCRIPTION OF THE DRAWINGS

FIG. 1 is a diagram illustrating an example of a substrate processing system to which a stocker device is applied.

FIG. 2 is a side cross-sectional view of the stocker device illustrated in FIG. 1.

FIG. 3 is a front view of the stocker device illustrated in FIG. 2.

FIG. 4 is a top plan view of the stocker device illustrated in FIG. 1.

FIG. 5 is a view taken along line A-A illustrated in FIG. 4.

FIGS. 6 and 7 are diagrams illustrating a state in which a moving frame is slid forwardly from a main frame.

FIG. 8 is a diagram illustrating a container transfer device.

FIGS. 9 to 12 are diagrams illustrating a transfer operation of a container in the stocker device.

FIG. 13 is a diagram illustrating a modified example of the substrate processing system.

FIG. 14 is a diagram illustrating a modified example of the container transfer device.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element may be directly coupled to or connected to the other constituent element, but intervening the other constituent elements may also be present. In contrast, when one constituent element is “directly coupled to or “directly connected to” another constituent element, it should be understood that there are no intervening element present. Other expressions describing the relationship between the constituent elements, such as “between ˜ and ˜”, “just between ˜ and ˜”, or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

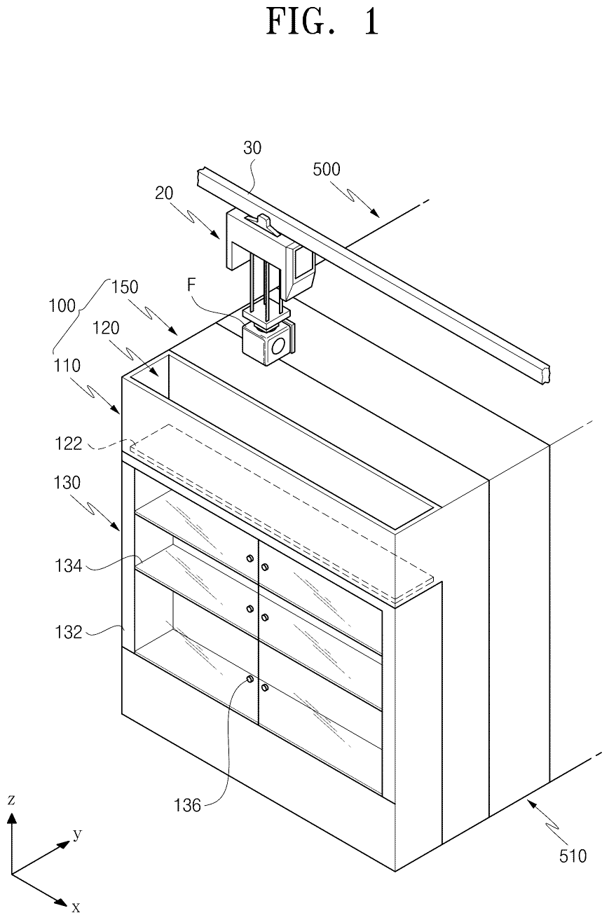

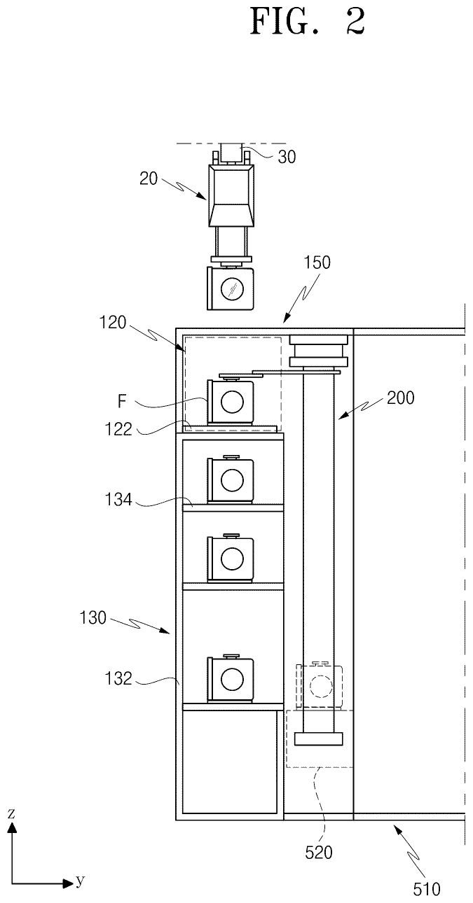

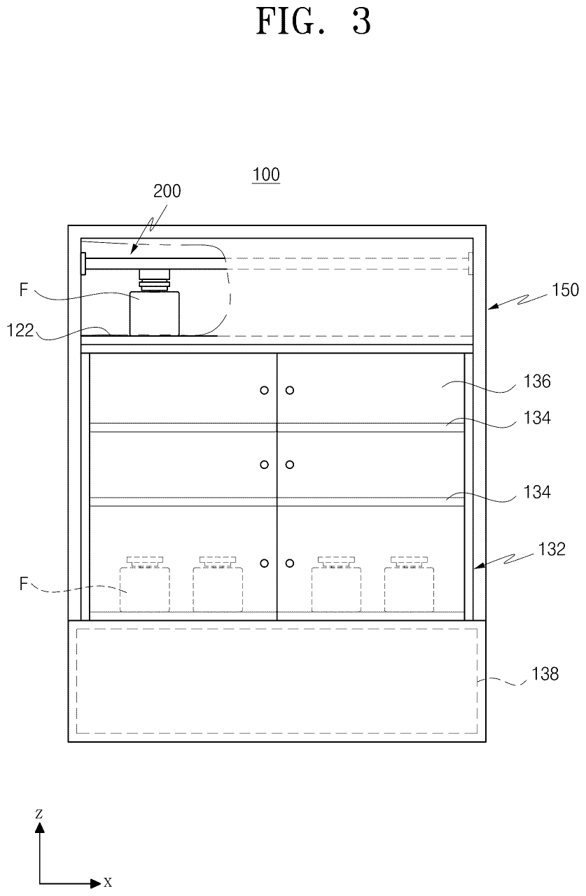

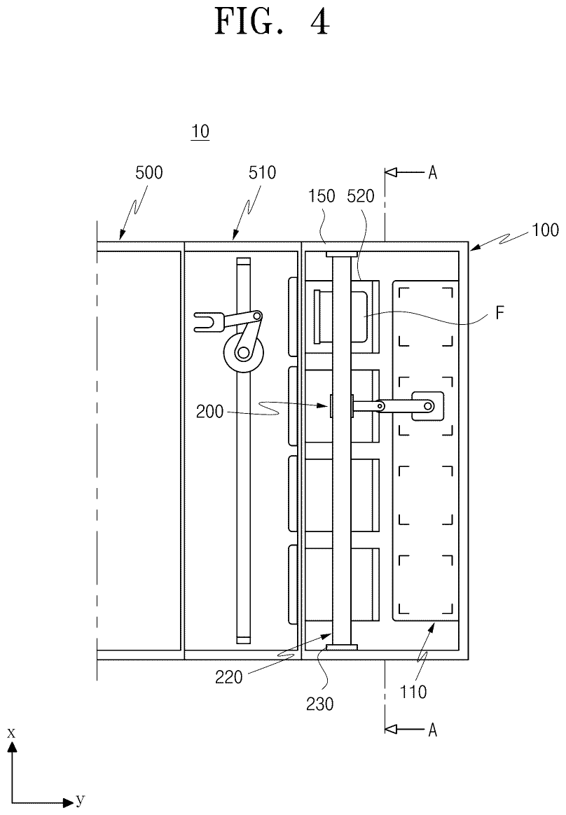

FIG. 1 is a diagram illustrating an example of a substrate processing system to which a stocker device is applied, FIG. 2 is a side cross-sectional view of the stocker device illustrated in FIG. 1, FIG. 3 is a front view of the stocker device illustrated in FIG. 2, and FIG. 4 is a top plan view of the stocker device illustrated in FIG. 1.

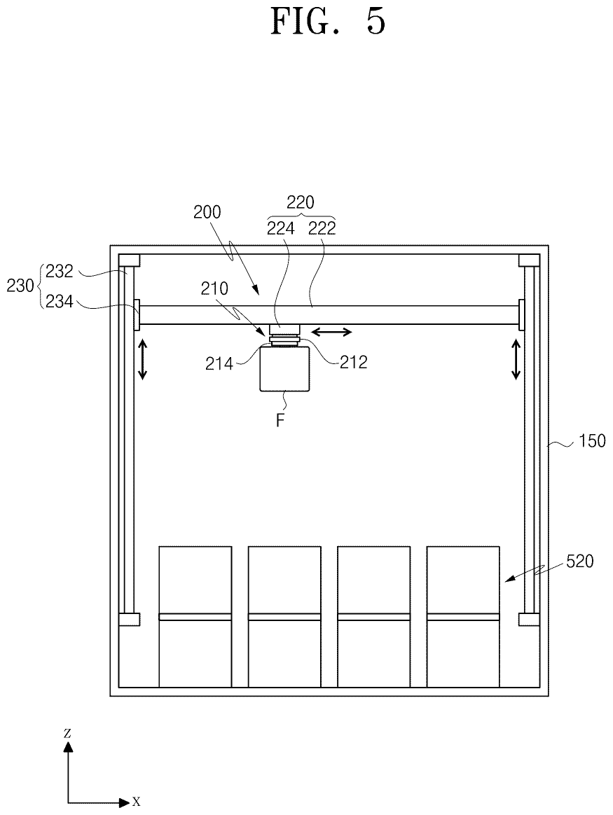

Referring to FIGS. 1 to 5, the substrate processing system 10 manufactures various devices, such as semiconductor devices and liquid crystal devices. The substrate processing system 10 forms a structure, such as a semiconductor device, wires, and an insulating film, on a substrate, such as a silicon wafer, to manufacture a semiconductor device. The substrate processing system 10 may include a processing apparatus main body 500 and a stocker device 100.

The processing apparatus main body 500 performs processing in a process of manufacturing a device. The processing apparatus main body 500 may be, for example, a film forming device, a coater/developer, an exposure device, or an etching device.

A container F containing articles related to processing is loaded and unloaded into and from the processing apparatus main body 500 through load ports 520 of an index unit 510. The article related to processing may include, for example, a substrate to be processed or an article (e.g., reticle) used for processing. The processing apparatus main body 500 receives the container F at the load port 520, takes out the substrate accommodated in the container F, and performs a predetermined process on the substrate. In addition, the processing apparatus 2 accommodates the substrate after the processing in the container F again and passes the container F to the load port 520. Herein, the container F may be a substrate storage container, such as a Front Opening Unified Pod (FOUP) in which a plurality of substrates is accommodated. An index robot 512 (see FIG. 4) is provided in the index unit 510.

A ceiling transfer trolley 20 is, for example, an OHT vehicle, and may be moved along a rail 30 installed in the ceiling (not illustrated) of the facility. The ceiling transfer trolley 20 transfers the container F from the outside of the substrate processing system 10 by gripping and moving the container F. For example, the ceiling transfer trolley 20 transfers the container F in which the article related to the processing of the processing apparatus main body 500 is accommodated. Further, the ceiling transfer trolley 20 receives the container F in which the article processed by the processing apparatus main body 500 is accommodated, and transfers the container F to another processing apparatus or the like. The ceiling transfer trolley 20 transfers the container F to a carrying-in/out shelf of a stocker device 100.

The stocker device 100 may be established in parallel in front of the processing apparatus main body 500. The stocker device 100 may be additionally installed in a processing apparatus main body already installed in a semiconductor manufacturing line. The stocker device 100 may be disposed in a transfer path between the ceiling transfer trolley 20 and the processing apparatus main body 500.

The stocker device 100 may include a loading unit 110 on which the container F is loaded, and a main frame 150 including a container transfer device 200 transferring the container F between the loading unit 110 and the load port 520.

The loading unit 110 is located in front of the load ports 520. The loading unit 110 may include a carrying-in/out loading unit 120 and a moving loading unit 130.

The carrying-in/out loading unit 120 includes a carrying-in/out shelf 122 through which the container F is transferred by the ceiling transfer trolley 20. The carrying-in/out shelf 122 may be provided to overlap the driving rail on which the ceiling transfer trolley 20 moves when viewed in a plan view.

The moving loading unit 130 may include a moving frame 132, a plurality of shelves 134 provided on the moving frame 132, and doors 136 provided on the front face of the moving frame 132. The shelves 134 may be arranged in multiple stages in the height direction inside the moving frame 132, and may be arranged in multiple in the horizontal direction. For example, four containers F may be stored in a horizontal direction in the first-stage shelf, and five containers may be stored in a horizontal direction in the second-stage shelf and the third-stage shelf. The floor height difference between the first-stage shelf and the second-stage shelf and the floor height difference between the second-stage shelf and the third-stage shelf may be different. For example, the floor height difference between the first-stage shelf and the second-stage shelf may be provided at a higher floor height than that of other floor heights. This is to prevent interference with the container placed on the load port 520 when the container transfer device 200 loads or unloads the container F into or from the first-stage shelf. A sensor (not illustrated) for detecting that the container F is mounted may be provided on the shelf 134. The sensor may be a contact type sensor, such as a button sensor, and by being pressed by the bottom surface of the container F, the sensor detects that the container F is loaded on the shelf 134.

The doors 136 may be provided so that an operator may load or unload a container F stored in the shelf 134 by the manual. The door 136 may be made of a transparent material to check the inside thereof.

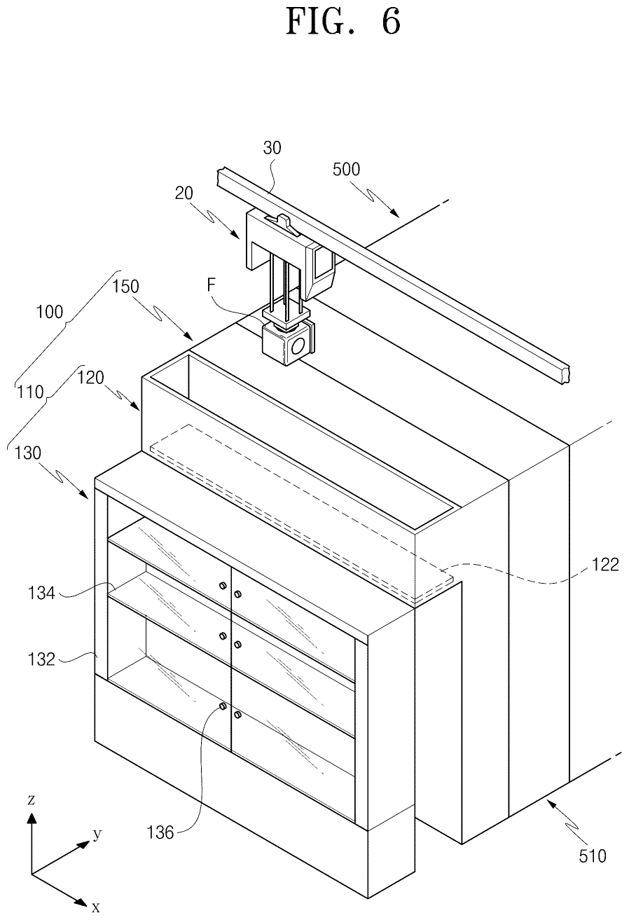

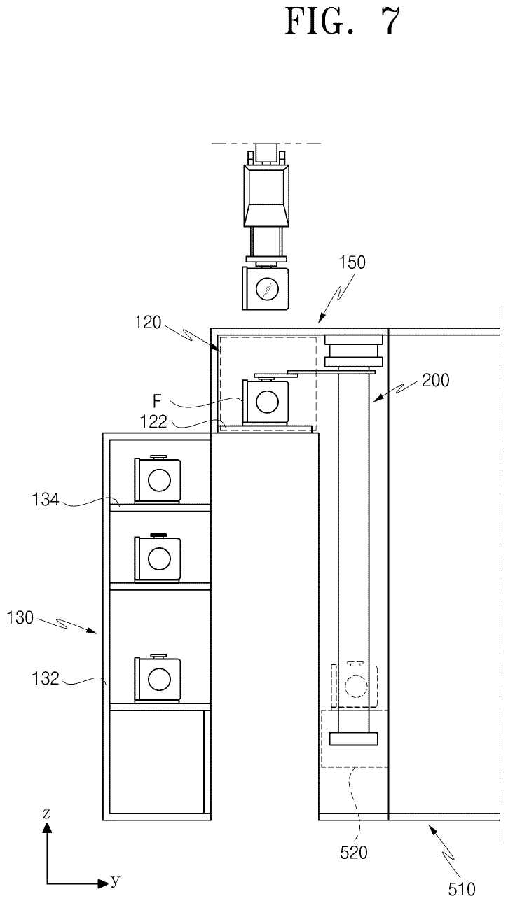

The moving loading unit 130 stores the container F transferred between the carrying-in/out loading unit 120 and the load port 520. As illustrated in FIGS. 6 and 7, the moving frame 132 may be provided to slide or open/close and move to the front from the main frame 150. Although not illustrated, the moving frame 132 may be moved along a wheel or a rail. When the moving frame 132 is moved forwardly from the main frame 150, an empty space is created between the moving frame 132 and the main frame 150, and an operator may easily perform maintenance of the stocker device 100 through the empty space.

The moving loading unit 130 may be provided with a separate storage space 138 below the first-stage shelf. A chemical liquid storage unit (not illustrated), a chemical liquid supply device (pump, filter, etc.) and the like may be disposed in the storage space 138.

Meanwhile, the carrying-in/out loading unit 120 is connected to the main frame 150. Therefore, even though the moving loading unit 130 is moved during the movement of the moving frame 132, the position of the carrying-in/out loading unit 120 is not changed. Therefore, when the moving loading unit 130 is docked to the main frame 150 again after the maintenance work of the stocker device 100 is completed, the position of the carrying-in/out shelf 122 may not be re-aligned.

The stocker device 100 receives the container F when the ceiling transfer trolley 20 transfers the container F to the carrying-in/out shelf 122 of the carrying-in/out loading unit 120, and temporarily stores the container F until the container F is handed over to the load port 520 of the processing apparatus main body 500. Accordingly, the next container F may be accommodated in the carrying-in/out loading unit 120. In addition, the stocker device 100 temporarily stores the container F unloaded from the processing apparatus main body 500, and passes the container F to the carrying-in/out loading unit 120 when the carrying-in/out loading unit 120 is empty. Thereby, in the carrying-in/out loading unit 120, the ceiling transfer trolley 20 is in a state in which the container F may be received. In this way, the stocker device 100 temporarily stores the container F, thereby reducing the waiting time of the ceiling transfer trolley 20, thereby increasing the transfer efficiency. In addition, the stocker device 100 temporarily stores the container F received from the ceiling transfer trolley 20, and then passes the container F to the load port 520 when the load port 520 of the processing apparatus main body 500 is empty. Thereby, the processing apparatus main body 500 may quickly receive the next container F after the process is completed. In addition, when the processing apparatus main body 500 unloads the container F from the load port 520, the stocker device 100 receives and temporarily stores the container F. Thereby, the processing apparatus main body 500 is capable of handing over the next container F to the load port 520. In this way, by temporarily storing the container F in the stocker device 100, the waiting time of the processing apparatus main body 500 may be reduced, and processing efficiency is increased.

The container transfer device 200 may transfer the container F in a space surrounded by the main frame 150. Specifically, the container transfer device 200 may transfer the container F in a space above the load ports 520. The stocker device 100 may minimize the occupied area occupied by the stocker device 100 by arranging the container transfer device 200 in the space above the load ports 520. In addition, the stocker device 100 may minimize the operation of the container transfer device 200 loading or unloading the container in the load port 520 by placing the container transfer device 200 in the space above the load ports 520.

The container transfer device 200 may transfer the container F between the carrying-in/out loading unit 120, the moving loading unit 130, and the load ports 520. For example, the container transfer device 200 may transfer the container F loaded from the ceiling transfer trolley 20 to the carrying-in/out shelf 122 to the shelf 134 of the moving loading unit 130. The container transfer device 200 may unload the container F stored in the shelf 134 of the moving loading unit 130 and transfer the container F to the empty load port 520. The container transfer device 200 may transfer the container F loaded from the ceiling transfer trolley 20 to the carrying-in/out loading unit 120 to the load port 520. In addition, the container transfer device 200 may transfer the container F in which the processed substrates are accommodated from the load port 520 to the shelf 134 of the moving loading unit 130 or the carrying-in/out shelf 122.

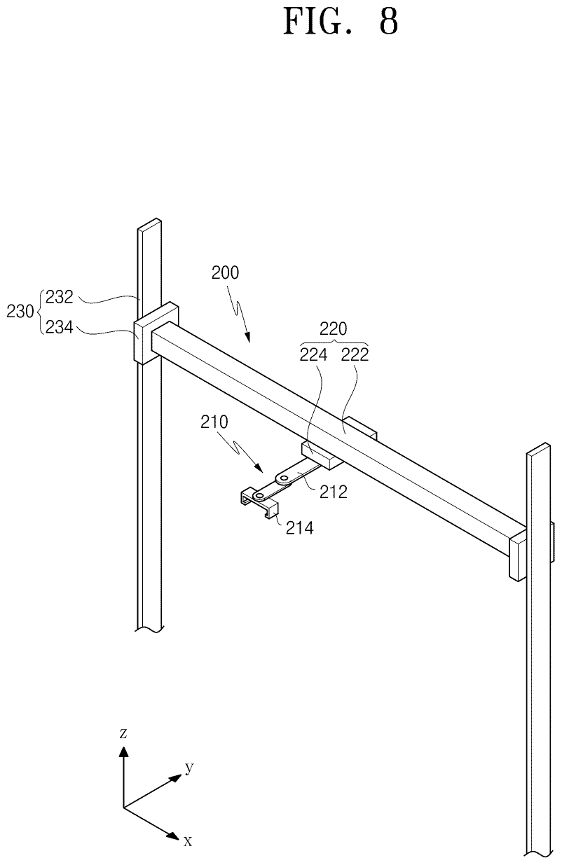

FIG. 8 is a diagram illustrating the container transfer device.

Referring to FIGS. 2, 4, 5, and 8, the container transfer device 200 may include a transfer robot 210, a horizontal driving unit 220, and a vertical driving unit 230.

The transfer robot 210 may include an arm 212 and a gripper 214. The arm 212 is a robot arm having one or more joints, and a gripper 214 may be provided at a front end thereof. The arm 26 may move the gripper 214 in the X direction and the Y direction, for example, by expanding and contracting a joint. The gripper 214 is inserted under a flange part of the container F and grips the container F. The arm 212 is capable of moving the container F in the X direction and the Y direction by expanding and contracting the joint while griping the container F by the gripper 214.

The horizontal driving unit 220 may include a horizontal guide 222 and a horizontal slider 224. The vertical driving unit 230 may include a vertical guide 232 and a vertical slider 234. The transfer robot 210 may be moved in the X direction and the Z direction by the horizontal driving unit 220 and the vertical driving unit 230.

The vertical guide 232 is mounted on opposite surfaces of the main frame 150 and extends in the Z direction (vertical direction). The vertical slider 234 is movable in the Z direction along the vertical guide 232. Both ends of the horizontal guide 222 are mounted on the vertical slider 234 and extend in the X direction (horizontal direction—the direction in which the load ports are arranged in a line). The horizontal guide 222 moves in the Z direction together with the vertical slider 234 when the vertical slider 234 moves. The horizontal slider 224 is movable in the X direction along the horizontal guide 222. When viewed from above, the horizontal guide 222 is located across the load ports 520.

The transfer robot 210 is mounted on the horizontal slider 224. When the horizontal slider 224 moves, the transfer robot 210 moves in the X direction together with the horizontal slider 224. Also, when the vertical slider 234 moves, the transfer robot 210 moves in the z direction together with the horizontal slider 224.

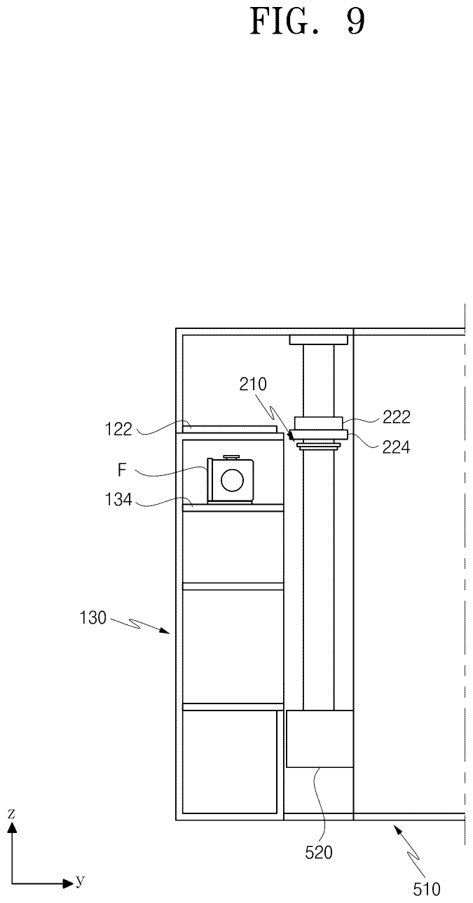

FIGS. 9 to 12 are diagrams illustrating a transfer operation of the container F in the stocker device 100.

Hereinafter, an operation of transferring the container F loaded on the shelves 122 and 134 of the loading unit 110 to the empty load port 520 will be described.

As illustrated in FIG. 9, before starting the container transfer operation, the container F is stored in the shelf 134. In the container transfer device 200, the transfer robot 210 moves in the X direction and the Z direction, so that the arm 212 is located slightly above the position facing the shelf 134.

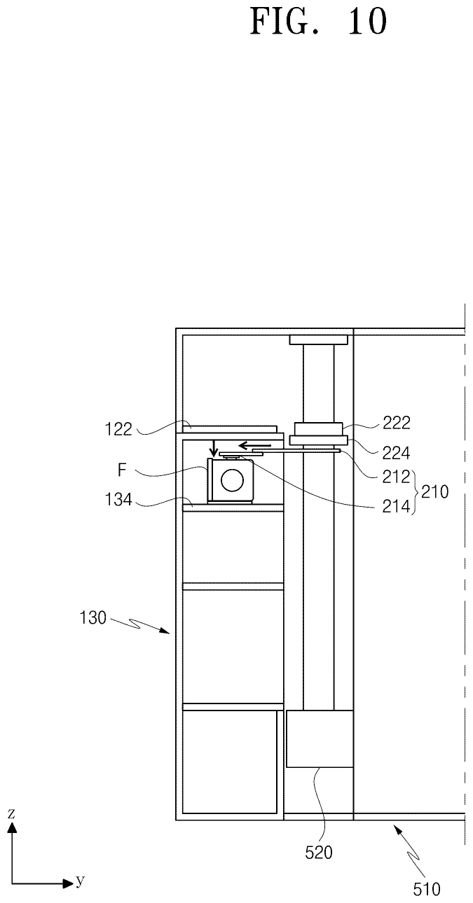

As indicated by an arrow in FIG. 10, the arm 212 of the transfer robot 210 extends, so that the gripper 214 moves upwardly from the container F stored in the shelf 134. In this state, the flange part of the container F is gripped by the gripper 214 by slightly lowering the transfer robot 210.

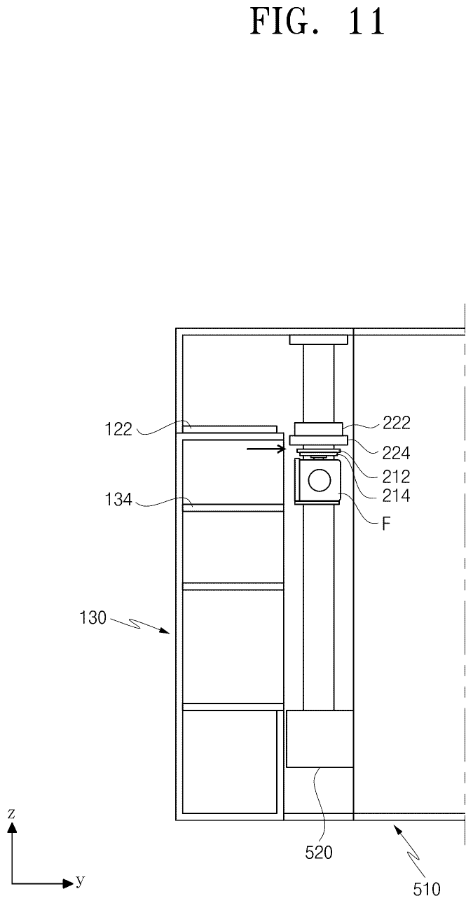

Next, as indicated by the arrow in FIG. 11, as the arm 212 contracts, the gripper 214 griping the container F moves below the horizontal slider 224 (in the main frame). Next, the transfer robot 210 moves horizontally onto the empty load port 520, and thus the container F is located above the load port 520.

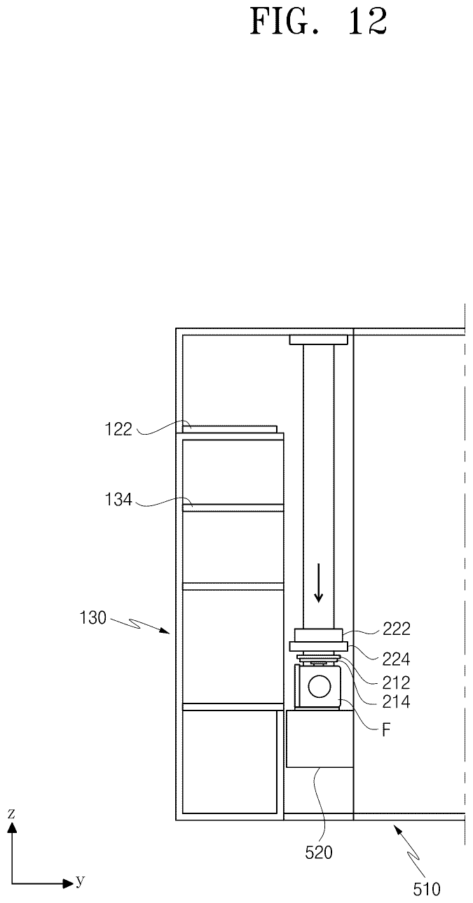

Next, as indicated by an arrow in FIG. 12, the container F is loaded on the load port 520 by moving the transfer robot 210 downwardly. Then, the gripping state of the container flange part by the gripper 214 is released. In this way, the transfer operation of the container F from the shelf 134 to the load port 520 is completed.

As described above, in the container transfer device 200, since the transfer robot 210 is located above the load port 520, the spreading operation of the arm 212 is required to receive the container F loaded on the loading unit 110, but the spreading operation of the arm 212 is not required to load or unload the container F onto or from the load port 520. Therefore, the spreading and folding operation of the arm 212 in the container transfer process between the shelves 122 and 134 and the load port 520 may be minimized, thereby shortening the container transfer time.

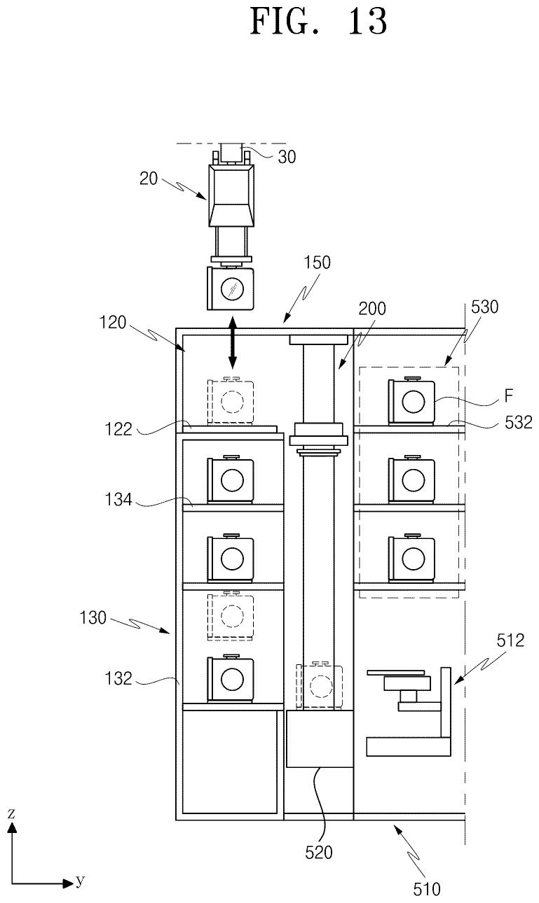

FIG. 13 is a diagram illustrating a modified example of the substrate processing system.

As illustrated in FIG. 13, the substrate processing system includes the processing apparatus main body 500 and the stocker device 100, which are provided with a configuration and function generally similar to the above-described exemplary embodiment, so hereinafter, a modified example will be described focusing on the difference from the present exemplary embodiment.

In the present modified example, an additional loading unit 530 may be provided in the index unit 510 of the processing apparatus main body 500. The additional loading unit 530 is located above the index robot 512 of the index unit 510. The additional loading unit 530 has a plurality of shelves 532. One surface of the additional loading unit 530 that is in contact with the main frame 150 may be open such that the container transfer device of the stocker device may load the container on the shelf 532. The additional loading unit 530 may be partitioned from the inner space of the index unit.

As described above, the present invention may expand the storage capacity of the container by adding the loading unit 530 capable of loading the container to the index unit 510.

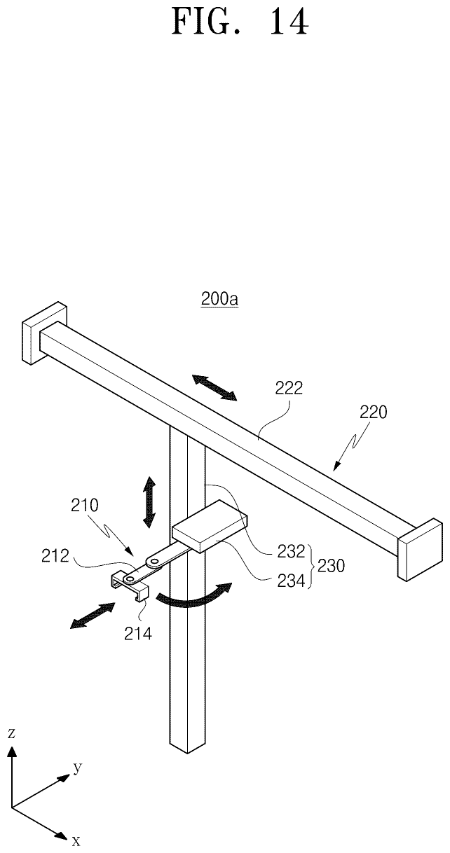

FIG. 14 is a diagram illustrating a modified example of the container transfer device.

Referring to FIG. 14, a container transfer device 200a may include a transfer robot 210, a horizontal driving unit 220, and a vertical driving unit 230, and these are provided with a configuration and function generally similar to that of the container transfer device illustrated in FIG. 8, and thus a modified example will be described below, focusing on differences from this exemplary embodiment.

In a modified exemplary embodiment, a horizontal driving unit 220 of the container transfer device 200a may include a horizontal guide 222. The horizontal guide 222 may be provided with the vertical guide 232 of the vertical driving unit 230 to be movable in the horizontal direction. When viewed from above, the horizontal guide 222 may be located across the load ports 520. Both ends of the vertical guide 232 may be fixed to the main frame 150. Although not illustrated, the horizontal guide 222 is provided with a horizontal slider movable along the horizontal guide 222, and the vertical guide 232 may be moved in the horizontal direction while being supported by the horizontal slider.

The vertical driving unit 230 may include a vertical guide 232 and a vertical slider 234. The vertical guide 232 is provided to be movable along the horizontal guide 222. The vertical slider 234 is provided to be movable in a vertical direction along the vertical guide 232.

The transfer robot 210 may be moved in the X direction and the Z direction by the horizontal driving unit 220 and the vertical driving unit 230. The transfer robot 210 may include an arm 212 and a gripper 214. The transfer robot 210 may be mounted on the vertical slider 234. The transfer robot 210 may move in the z direction together with the vertical slider 234. Also, when the vertical guide 232 moves in the horizontal direction, the transfer robot 210 may move in the horizontal direction together with the vertical guide.

The foregoing exemplary embodiments are presented for helping the understanding of the present invention, and do not limit the scope of the present invention, and it should be understood that various modified exemplary embodiments from the foregoing exemplary embodiments are also included in the scope of the present invention. The technical protection scope of the present invention should be determined by the technical spirit of the claims, and it should be understood that the technical protection scope of the present invention is not limited to the literal description of the claims itself, but is substantially equivalent to the technical value.

What is claimed is:

1. A stocker device provided on a front face of a substrate processing apparatus in which load ports are placed horizontally, the stocker device comprising:
a loading unit located in front of the load ports and including shelves configured to store substrate accommodation containers; and
a main frame including a container transfer device configured to transfer the substrate accommodation container between the shelves and the load port,
wherein the container transfer device is located above the load ports.

2. The stocker device of claim 1, wherein the loading unit includes:
a carrying-in/out loading unit including a carrying-in/out shelf where the substrate accommodation container is loaded and unloaded by a ceiling transfer trolley; and
a main loading unit including storage shelves configured to store the substrate accommodation containers transferred between the carrying-in/out loading unit and the load port.

3. The stocker device of claim 2, wherein the loading unit is configured to slide or open/close and move to the front of the main frame to secure a space for maintenance.

4. The stocker device of claim 2, wherein the carrying-in/out loading unit is located over the main loading unit.

5. The stocker device of claim 4, wherein the carrying-in/out loading unit is fixedly installed on the main frame, and
the main loading unit is configured to slide or open/close and move to the front of the main frame to secure a space for maintenance.

6. The stocker device of claim 2, wherein the main loading unit is configured such that the shelves are arranged in multiple stages in a vertical direction, and
a first-stage shelf located at the lowermost stage among the shelves and a second-stage shelf located directly over the first-stage shelf have a greater floor height than other shelves.

7. The stocker device of claim 1, wherein a shelf located at the topmost portion of the loading unit is configured to allow the substrate accommodation container to be transferred between the shelf and a ceiling traveling trolley.

8. The stocker device of claim 2, wherein the container transfer device includes:
a transfer robot including an arm configured to grip the substrate accommodation container;
a horizontal driving unit configured to move the transfer robot in a horizontal direction; and
a vertical driving unit configured to move the transfer robot in a vertical direction.

9. The stocker device of claim 8, wherein the horizontal driving unit is located above the load ports.

10. The stocker device of claim 8, wherein the transfer robot is configured to perform loading and unloading of the substrate transfer container on the carrying-in/out shelf or the storage shelf with the arm in an extended state, and
to perform loading and unloading of the substrate transfer container on the load port with the arm in a folded state.

11. A substrate processing apparatus comprising:
a main body including an index unit in which load ports, on which substrate accommodation containers are placed, are horizontally arranged on a front face; and
a stocker device located in front of the index unit and configured to load and unload the substrate accommodation container,
wherein the stocker device includes:
a loading unit located in front of the load ports and configured to store the substrate accommodation container; and
a main frame including a container transfer device configured to transfer the substrate accommodation container between the loading unit and the load port in a space above the load ports.

12. The substrate processing apparatus of claim 11, wherein the loading unit is configured to slide to the front of the main frame to secure a space for maintenance.

13. The substrate processing apparatus of claim 12, wherein the loading unit includes:
a carrying-in/out loading unit including a carrying-in/out shelf where the substrate accommodation container is loaded and unloaded by a ceiling transfer trolley; and
a main loading unit including storage shelves storing the substrate accommodation container transferred between the carrying-in/out loading unit and the load port.

14. The substrate processing apparatus of claim 13, wherein the carrying-in/out loading unit is located over the main loading unit,
the index unit further includes an additional loading unit accessible by the container transfer device and configured to store the substrate accommodation container, and
the additional loading unit is located above an index robot of the index unit.

15. The substrate processing apparatus of claim 13, wherein the carrying-in/out loading unit is fixedly installed on the main frame, and
the main loading unit configured to slide to the front of the main frame to secure a space for maintenance.

16. The substrate processing apparatus of claim 13, wherein the main loading unit is configured such that the shelves are arranged in multiple stages in a vertical direction, and
a first-stage shelf located at the lowermost stage among the shelves and a second-stage shelf located directly over the first-stage shelf have a greater floor height than other shelves.

17. The substrate processing apparatus of claim 12, wherein the container transfer device includes:
a transfer robot including an arm configured to grip the substrate accommodation container;
a horizontal driving unit configured to move the transfer robot in a horizontal direction; and
a vertical driving unit configured to move the transfer robot in a vertical direction, and
the horizontal driving unit is located above the load ports, and
the transfer robot configured to perform loading and unloading of the substrate transfer container on the load port with the arm in a folded state.

18. A substrate processing apparatus comprising:
a main body including a processing unit equipped with processing apparatuses that perform predetermined processing on a substrate, and an index unit which is located in front of the processing unit and in which load ports, on which substrate accommodation containers are placed, are horizontally arranged on a front face; and
a stocker device located in front of the index unit and configured to load and unload the substrate accommodation container,
wherein the stocker device includes:
a loading unit including carrying-in/out shelves that are located in front of the load ports and where the substrate accommodation container is loaded and unloaded bya ceiling transfer trolley, and storage shelves located under the carrying-in/out shelves and configured to store the substrate accommodation container transferred between the carrying-in/out shelf and the load port; and
a main frame including a container transfer device configured to transfer the substrate accommodation container between the loading unit and the load port in a space above the load ports, and
the loading unit further includes a moving frame slidably configured to move to the front of the main frame, and the storage shelves are arranged in multiple stages in a vertical direction on the moving frame.

19. The substrate processing apparatus of claim 18, wherein the carrying-in/out shelves are fixedly installed on the main frame, and
a storage shelf in a first stage located at the lowermost stage among the storage shelves and a storage shelf located in a storage shelf directly over the storage shelf in the first stage have a greater floor height than other storage shelves, and
the index unit further includes an additional loading unit accessible by the container transfer device and configured to store the substrate accommodation container, and
the additional loading unit is located above an index robot of the index unit.

20. The substrate processing apparatus of claim 18, wherein the container transfer device includes:
a transfer robot including an arm configured to grip the substrate accommodation container;
a horizontal driving unit located above the load ports and configured to move the transfer robot in a horizontal direction; and
a vertical driving unit configured to move the transfer robot in a vertical direction, and
the transfer robot configured to perform loading and unloading of the substrate transfer container on the carrying-in/out shelf or the storage shelf with the arm in an extended state, and
to perform loading and unloading of the substrate transfer container on the load port with the arm in a folded state.
